(19) United States
(12) Patent Application Publication
(10) Pub. No.: US 2025/0169012 A1
(43) Pub. Date: May 22, 2025

(54) User-Exposed and Variably-Thick Cover Glass for Foldable Displays

(71) Applicant: Google LLC, Mountain View, CA (US)

(72) Inventors: Michael J. Lombardi, South Barrington, IL (US); Mike Liu, Mountain View, CA (US); Avi Pinchas Hecht, San Francisco, CA (US)

(73) Assignee: Google LLC, Mountain View, CA (US)

(21) Appl. No.: 18/780,036

(22) Filed: Jul. 22, 2024

Related U.S. Application Data
(60) Provisional application No. 63/601,629, filed on Nov. 21, 2023.

(51) Int. Cl. H05K 5/03

(52) U.S. Cl. CPC H05K 5/03

(57) ABSTRACT

This document describes systems and techniques directed at user-exposed and variably-thick cover glass for foldable displays. In aspects, a foldable display structure includes a glass layer and an optically-clear adhesive disposed thereunder. The glass layer includes a first groove on a top face along a first plane and a second groove on a bottom face along the first plane. In implementations, the first groove and the second groove form a variable thickness in the glass layer along a dimension of the glass layer perpendicular to the first plane sufficient to define a foldable region. Through such an implementation, the glass layer may be exposed to an external environment, improving a durability, material-finish, and a reliability of foldable display structures.

### CROSS-REFERENCE TO RELATED APPLICATION(S)

This application claims priority to U.S. Provisional Patent Application Ser. No. 63/601,629, filed on Nov. 21, 2023, the disclosure of which is incorporated by reference herein in its entirety.

### SUMMARY

This document describes systems and techniques directed at user-exposed and variably-thick cover glass for foldable displays. In aspects, a foldable display structure includes a glass layer and an optically-clear adhesive disposed thereunder. The glass layer includes a first groove on a top face along a first plane and a second groove on a bottom face along the first plane. In implementations, the first groove and the second groove form a variable thickness in the glass layer along a dimension of the glass layer perpendicular to the first plane sufficient to define a foldable region. Through such an implementation, the glass layer may be exposed to an external environment, improving a durability, material-finish, and a reliability of foldable display structures.

In implementations, a foldable display structure is disclosed that includes a glass layer having a top face and an opposing bottom face. The glass layer may be positioned as the topmost layer of the foldable display structure. The glass layer includes a first groove on the top face of the glass layer along a first plane and a second groove on the bottom face of the glass layer along the first plane. The first groove and the second groove may form a variable thickness in the glass layer along a dimension of the glass layer perpendicular to the first plane sufficient to define a foldable region. The foldable display structure further includes a first resin deposited within the first groove such that the first resin is contiguous with the top face of the glass layer. The foldable display structure further includes a second resin deposited within the second groove and an optically-clear adhesive layer positioned underneath the glass layer and the second resin.

This Summary is provided to introduce simplified concepts of systems and techniques directed at user-exposed and variably-thick cover glass for foldable displays, the concepts of which are further described below in the Detailed Description and Drawings. This Summary is not intended to identify essential features of the claimed subject matter, nor is it intended for use in determining the scope of the claimed subject matter.

### BRIEF DESCRIPTION OF THE DRAWINGS

The details of one or more aspects of systems and techniques directed at user-exposed and variably-thick cover glass for foldable displays are described in this document with reference to the following drawings:

FIG. 1 illustrates an example implementation of an example foldable electronic device with a user-exposed and variably-thick cover glass in accordance with one or more implementations;

FIG. 2 illustrates example foldable electronic devices in which user-exposed and variably-thick cover glass for foldable displays can be implemented;

FIG. 3 illustrates three example implementations of the glass layer in accordance with one or more implementations;

FIG. 4 illustrates an example implementation of the display with more detail in accordance with one or more implementations;

FIG. 5 illustrates an example manufacturing process in accordance with one or more implementations;

FIG. 6 illustrates two example implementations of a glass layer including a non-uniform chemical strengthening depth; and

FIG. 7 illustrates an example implementation of a display in accordance with one or more implementations.

The same numbers are used throughout the Drawings to reference like features and components.

### DETAILED DESCRIPTION

### Overview

Many electronic devices include displays, such as light-emitting diode (LED) displays or liquid crystal displays (LCDs). Electronic device manufacturers often fabricate displays in a layered structure (“display panel stack”). The display panel stack includes a display module having a display panel that, when integrated into an electronic device, is disposed underneath and shielded by a cover layer (e.g., a glass layer). The display panel stack may further include one or more of a touch layer (e.g., touch sensor panel), a polarizer layer (e.g., polarization filters), an adhesive layer, and/or a protective layer (e.g., an EMBO layer).

The protective layer may include one or more sublayers, such as a polymer sublayer (e.g., polyethylene terephthalate (PET) substrate), a metallic sublayer (e.g., copper, stainless steel), a foam pad (e.g., to absorb compressive forces during manufacturing or usage), or an adhesive sublayer. The protective layer shields delicate display panels from both mechanical and electromagnetic forces, as well as from thermal radiation.

Any physical or electrical damage to a display panel can quickly render portions of the display panel inoperable, spoiling user experience. Thus, display panels are handled with great care during manufacturing and are often surrounded by many shielding components, including the protective layer and the cover layer, for protection during manufacturing and/or device usage. Not only are display panels delicate, but they are also elaborate, requiring sophisticated manufacturing techniques to intricately design an array of pixel circuits within the display of the display module. Pixel arrays include tens of thousands of pixels organized into a two-dimensional grid (e.g., a circular or rectangular grid). Each of the pixel circuits may include an organic light-emitting diode (“pixel”) composed of, for example, a red sub-pixel, a green sub-pixel, and/or a blue sub-pixel. To power and control the pixel array, display modules often include routing circuitry, surrounding a perimeter of the pixel array, connecting the pixels to one or more drivers. In one example, a pixel array having a two-dimensional rectangular grid of pixels is operably coupled to one or more row-line drivers via electrical traces (e.g., wires). Electronic devices can, via the one or more drivers, control any of the pixels within a display panel to illuminate at various intensities and wavelengths (e.g., combined wavelengths of the sub-pixels), effective to produce on-screen content (e.g., images). Such display panels are well-suited for electronic devices, and are further appreciated by users, in large part, because of their image quality.

To provide users with large display experiences in small display form factors, manufacturers may design electronic devices, including at least portions of display panel stacks, to fold into one or more configurations (“foldable devices”). A foldable device, with a foldable display, can include one or more primary folding regions and one or more secondary folding regions. The folding regions may fold towards or away from each other to achieve one of a variety of foldable display shapes, such as a ‘V’ shape, ‘Z’ shape, or ‘C’ shape. One foldable display shape may be chosen over another foldable display shape based on design consolations, such as having the foldable display on an inside or an outside of the foldable device when in a folded position. Commonly, a foldable display includes one primary folding region that divides the display into two equal segments and two secondary folding regions that are generally equidistant from the primary folding region.

Such foldable devices are prized by users for their maximized display size and small form factor. However, these foldable devices may suffer from a perception of poor perceived quality due to manufacturers using thin plastic and/or glass layers (e.g., ultra-thin glass) in display panel stacks that are susceptible to warpage, scratching, and facture.

To this end, this document describes systems and techniques directed at user-exposed and variably-thick cover glass for foldable displays. In aspects, a foldable display structure includes a glass layer and an optically-clear adhesive disposed thereunder. The glass layer includes a first groove on a top face along a first plane and a second groove on a bottom face along the first plane. In implementations, the first groove and the second groove form a variable thickness in the glass layer along a dimension of the glass layer perpendicular to the first plane sufficient to define a foldable region. Through such an implementation, the glass layer may be exposed to an external environment, improving a durability, material-finish, and a reliability of foldable display structures.

### Example Implementations

The following discussion describes example implementations, techniques, apparatuses that may be employed in the example implementations, and various devices in which components of user-exposed and variably-thick cover glass for foldable displays can be embodied. In the context of the present document, reference is made to the following by way of example only.

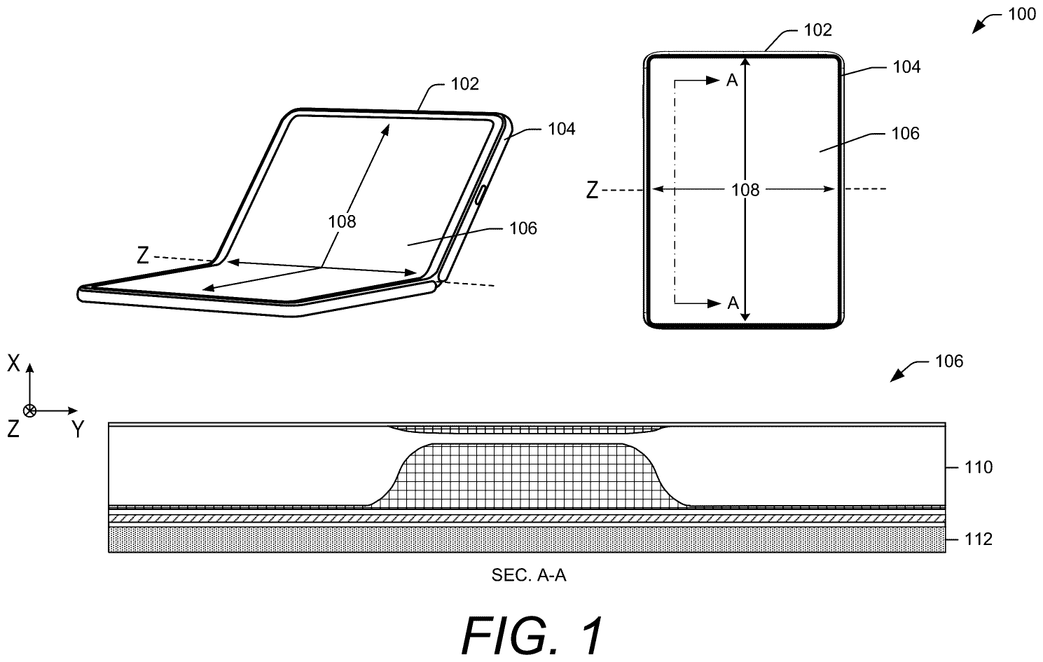

FIG. 1 illustrates an example implementation 100 of an example foldable electronic device 102 with a user-exposed and variably-thick cover glass in accordance with one or more implementations. As illustrated, the example foldable electronic device 102 includes a housing 104 (e.g., a frame) and a display 106 (e.g., a display panel stack). The foldable electronic device 102 may be configured to fold along one or more axes (e.g., a Z-axis). The foldable electronic device 102 includes an active area 108 defined by at least one of the housing 104 or an opaque border (not labelled) surrounding a perimeter of the display 106.

The display 106 of the foldable electronic device 102 includes a glass layer 110 (e.g., cover glass) and a display panel module 112. In implementations, the glass layer 110 is exposed to an external environment surrounding the foldable electronic device 102 and includes a variable thickness along at least one dimension of the foldable electronic device 102 (e.g., a width of the device). The glass layer 110 protects the display panel 112 and serves as a barrier to ingress contaminants (e.g., dust, dirt, water).

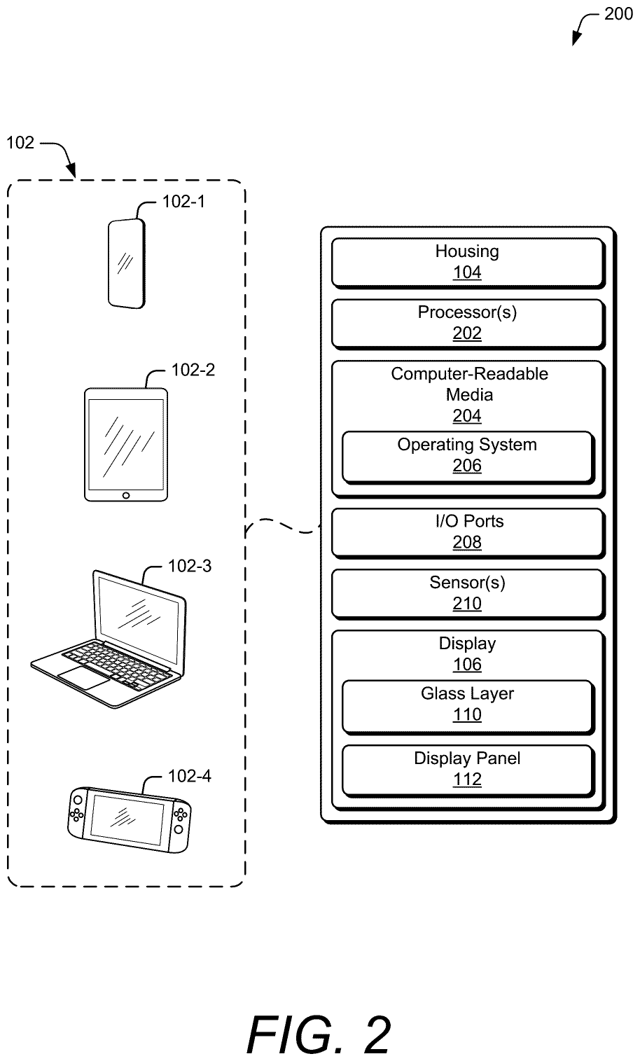

FIG. 2 illustrates example foldable electronic devices 102 in which user-exposed and variably-thick cover glass for foldable displays can be implemented. The foldable electronic devices 102 may include additional components and interfaces omitted from FIG. 2 for the sake of clarity.

The foldable electronic devices 102 can be any of a variety of consumer electronic devices. As non-limiting examples, the foldable electronic device 102 can be a mobile phone 102-1, a tablet device 102-2, a laptop computer 102-3, a portable video game console 102-4, and the like.

The foldable electronic device 102 includes the housing 104 which defines at least one internal cavity within which one or more of a plurality of electronic components may be disposed. In implementations, a mechanical frame may define one or more portions of the housing 104. As an example, a mechanical frame can include plastic or metallic walls that define portions of the housing 104. In additional implementations, a mechanical frame may support one or more portions of the housing 104. As an example, one or more exterior housing components (e.g., plastic panels) can be attached to the mechanical frame (e.g., a chassis). In so doing, the mechanical frame physically supports the one or more exterior housing components, which define portions of the housing 104. In implementations, the mechanical frame and/or the exterior housing components may be composed of crystalline or non-crystalline (e.g., metals, plastics) inorganic solids.

These mechanical frames can be designed in a variety of configurations. In implementations, the mechanical frame may be designed with a bucket architecture. As an example, a mechanical frame designed with a bucket architecture defines an open-sided polyhedron (e.g., an open-sided rectangular prism). In additional implementations, the mechanical frame may be designed with a mid-frame architecture. In either architecture, a mechanical frame may include more than one open side, defining a partial or full skeletal polyhedron (e.g., a polyhedron structure in which vertices and edges are defined by rods and two or more faces are absent). Exterior housing components (e.g., plastic panels) can then be attached to the mechanical frame to define an open-sided polyhedron. In any implementation, the housing 104 may be sealed through the inclusion of a display (e.g., the cover layer 110), defining at least one internal cavity.

The foldable electronic device 102 may further include one or more processors 202. The processor(s) 202 can include, as non-limiting examples, a system on a chip (SoC), an application processor (AP), a central processing unit (CPU), or a graphics processing unit (GPU). The processor(s) 202 generally execute commands and processes utilized by the foldable electronic device 102 and an operating system installed thereon. For example, the processor(s) 202 may perform operations to display graphics of the foldable electronic device 102 on a display 106 and can perform other specific computational tasks.

The foldable electronic device 102 may also include computer-readable storage media (CRM) 304. The CRM 204 may be a suitable storage device configured to store device data of the foldable electronic device 102, user data, and multimedia data. The CRM 204 may store an operating system 206 that generally manages hardware and software resources (e.g., the applications) of the foldable electronic device 102 and provides common services for applications stored on the CRM 204. The operating system 206 and the applications are generally executable by the processor(s) 202 to enable communications and user interaction with the foldable electronic device 102. One or more processor(s) 202, such as a GPU, perform operations to display graphics of the foldable electronic device 102 on the display 106 and can perform other specific computational tasks. The processor(s) 202 can be single-core or multiple-core processors.

The foldable electronic device 102 may also include input/output (I/O) ports 208. The I/O ports 208 allow the foldable electronic device 102 to interact with other devices or users. The I/O ports 208 may include any combination of internal or external ports, such as universal serial bus (USB) ports, audio ports, Serial ATA (SATA) ports, PCI-express based ports or card-slots, secure digital input/output (SDIO) slots, and/or other legacy ports.

The foldable electronic device 102 may further include one or more sensors 210. The sensor(s) 210 can include any of a variety of sensors, such as an audio sensor (e.g., a microphone), a touch-input sensor (e.g., a touchscreen), an image-capture device (e.g., a camera, video-camera), proximity sensors (e.g., capacitive sensors), an under-display fingerprint sensor, or an ambient light sensor (e.g., photodetector). In implementations, the foldable electronic device 102 may include one or more of a front-facing sensor(s) and a rear-facing sensor(s).

Further, the foldable electronic device 102 includes the display 106 (e.g., a display panel stack) having a glass layer 110 and a display panel 112. Although systems and techniques described herein describe the use of the glass layer 110, it should be understood to those skilled in the art that the glass layer 110 may be substituted with any of a variety of transparent materials including polymers (e.g., plastic, acrylic). The glass layer 110 may form any foldable, three-dimensional shape.

The display panel 112 may include a two-dimensional pixel array (not illustrated in FIG. 2) forming a grid, operably coupled to one or more row-line drivers via electrical traces. The pixel array generates light to create an image on the display 106 upon electrical activation by one or more drivers. As an example, data-line drivers provide voltage data via electrical traces to the pixel array to control luminance levels of individual pixels.

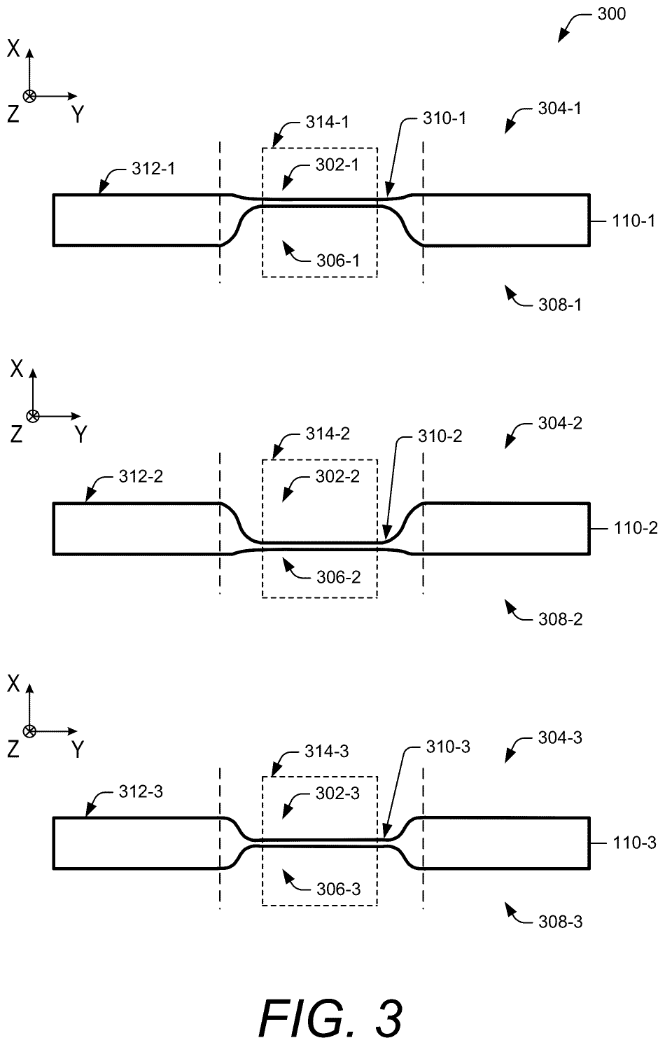

FIG. 3 illustrates three example implementations 300 of the glass layer 110 in accordance with one or more implementations. As illustrated, a first glass layer 110-1 includes a first groove 302-1 on a top face 304-1 and a second groove 306-1 on a bottom face 308-1 (e.g., the top face 304-1 being exposed to an ambient environment, the bottom face 308-1 positioned proximally closer to a display panel). For the first glass layer 110-1, the first groove 302-1 is shallower in depth than the second groove 306-1. In at least some implementations, a width of the first groove 302-1 is narrower than a width of the second groove 306-1. In still further implementations, the first groove 302-1 and the second groove 306-1 are aligned, for example, along an X-axis.

Further illustrated, the first groove 302-1 and the second groove 306-1 form a variable thickness in the first glass layer 110-1 along at least one dimension of the first glass layer 110-1 (e.g., a dimension perpendicular to a length of the groove, the Y-axis). The first groove 302-1 and the second groove 306-1 may define, in the first glass layer 110-1, a thin region 310-1 and at least one thick region 312-1. In implementations, a ratio of the dimensional-thickness between the at least one thick region 312-1 and the thin region 310-1 may be at least six-to-one. In one example, the at least one thick region 312-1 may be 200 micrometers thick, while the thin region 310-1 may be 30 micrometers thick. While other foldable display structures may utilize, for example, ultra-thin glass that is at most 70-100 micrometers thick, the first glass layer 110-1 may be much thicker, providing better reliability and hardness.

At least portions of the first groove 302-1 and the second groove 306-1 define a foldable region 314-1. For example, a portion of the thin region 310-1 may bend when mechanical forces are applied to the at least one thick region 312-1. A thickness in the foldable region 314-1 and/or a thickness in non-folding regions at least partially determine a mechanical strength of the first glass layer 110-1. In implementations, a mechanical strength of the first glass layer 110-1 sufficient to satisfy a predetermined factor of safety is required to withstand consumer use. The mechanical strength may at least partially determine the thickness in the foldable region 312-1 and/or the thickness in non-folding regions.

Further illustrated, a second glass layer 110-2 includes a first groove 302-2 on a top face 304-2 and a second groove 306-2 on a bottom face 308-2 (e.g., the top face 304-2 being exposed to an ambient environment, the bottom face 308-2 positioned proximally closer to a display panel). For the second glass layer 110-2, the first groove 302-2 is greater in depth than the second groove 306-2. In at least some implementations, a width of the first groove 302-2 is wider than a width of the second groove 306-2. In still further implementations, the first groove 302-2 and the second groove 306-2 are aligned, for example, along an X-axis.

Further illustrated, the first groove 302-2 and the second groove 306-2 form a variable thickness in the second glass layer 110-2 along at least one dimension of the second glass layer 110-2 (e.g., a dimension perpendicular to a length of the groove, the Y-axis). The first groove 302-2 and the second groove 306-2 may define, in the second glass layer 110-2, a thin region 310-2 and at least one thick region 312-2. In implementations, a ratio of the dimensional-thickness between the at least one thick region 312-2 and the thin region 310-2 may be at least six-to-one. In one example, the at least one thick region 312-2 may be 200 micrometers thick, while the thin region 310-2 may be 30 micrometers thick. While other foldable display structures may utilize, for example, ultra-thin glass that is at most 70-100 micrometers thick, the second glass layer 110-2 may be much thicker, providing better reliability and hardness.

At least portions of the first groove 302-2 and the second groove 306-2 define a foldable region 314-2. For example, a portion of the thin region 310-2 may bend when mechanical forces are applied to the at least one thick region 312-2. A thickness in the foldable region 314-2 and/or a thickness in non-folding regions at least partially determine a mechanical strength of the second glass layer 110-2.

Further illustrated, a third glass layer 110-3 includes a first groove 302-3 on a top face 304-3 and a second groove 306-3 on a bottom face 308-3 (e.g., the top face 304-3 being exposed to an ambient environment, the bottom face 308-3 positioned proximally closer to a display panel). For the second glass layer 110-3, the first groove 302-3 is equal in depth to the second groove 306-3. In at least some implementations, a width of the first groove 302-3 is equal to a width of the second groove 306-3. In still further implementations, the first groove 302-3 and the second groove 306-3 are aligned, for example, along an X-axis. As illustrated, the third glass layer 110-3 may be symmetrical along two or more dimensions (e.g., a Z-axis, a Y-axis).

Further illustrated, the first groove 302-3 and the second groove 306-3 form a variable thickness in the third glass layer 110-3 along at least one dimension of the third glass layer 110-3 (e.g., a dimension perpendicular to a length of the groove, the Y-axis). The first groove 302-3 and the second groove 306-3 may define, in the third glass layer 110-3, a thin region 310-3 and at least one thick region 312-3. In implementations, a ratio of the dimensional-thickness between the at least one thick region 312-3 and the thin region 310-3 may be at least six-to-one. In one example, the at least one thick region 312-3 may be 200 micrometers thick, while the thin region 310-3 may be 30 micrometers thick. While other foldable display structures may utilize, for example, ultra-thin glass that is at most 70-100 micrometers thick, the third glass layer 110-3 may be much thicker, providing better reliability and hardness.

At least portions of the first groove 302-3 and the second groove 306-3 define a foldable region 314-3. For example, a portion of the thin region 310-3 may bend when mechanical forces are applied to the at least one thick region 312-3. A thickness in the foldable region 314-3 and/or a thickness in non-folding regions at least partially determine a mechanical strength of the third glass layer 110-3.

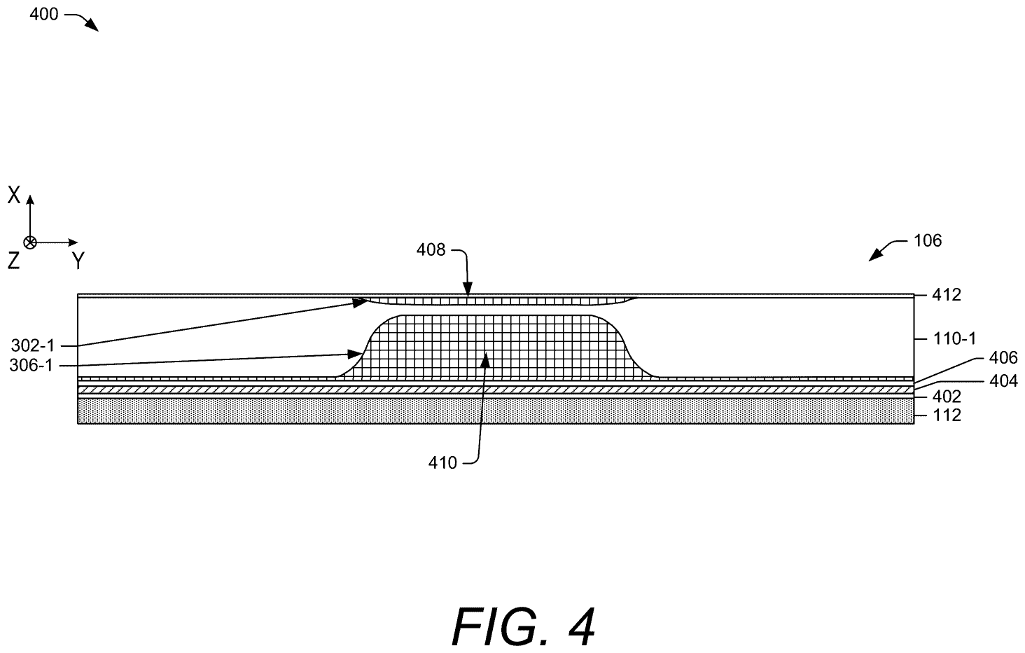

FIG. 4 illustrates an example implementation 400 of the display 106 with more detail in accordance with one or more implementations. As illustrated, the display 106 includes the first glass layer 110-1 (for example only and not by way of limitation) and the display panel 112. The display 106 may further include a permanent optically-clear adhesive layer 402, which adheres the display panel 112 to a permanent protective layer 404. In implementations, the permanent optically-clear adhesive layer 402 and the permanent protective layer 404 are configured to remain affixed to the display panel 112 when, for example, the first glass layer 110-1 is removed for service. Thus, the permanent optically-clear adhesive layer 402 may include a stronger bond than, for example, a removeable optically-clear adhesive layer 406. The removeable optically-clear adhesive layer 406 may deposited on a face of the permanent protective layer 404 opposite of the permanent optically-clear adhesive layer 402.

In aspects, the first groove 302-1 and the second groove 306-1 of the first glass layer 110-1 are filled with a first resin 408 and a second resin 410, respectively. In implementations, the first resin 408 fills only the first groove 302-1 such that the first resin 408 is contiguous with the top face 304-1 (not labeled in FIG. 4) of the first glass layer 110-1. For example, the first resin 408 is flush with a surface of the top face 304-1. In further implementations, the second resin 410 extends beyond the second groove 306-1, covering an entire surface of the bottom face 308-1 (not labeled in FIG. 4) of the first glass layer 110-1. For example, the second resin 410 is disposed between all portions of the permanent protective layer 404 and the first glass layer 110-1. In at least some implementations, the second resin 410 fills only the second groove 306-1 such that the second resin 410 is contiguous with the bottom face 308-1.

In implementations, the first resin 408 includes a compression-cyclable resin. The compression-cyclable resin includes a compression-survivable index matched resin. In further implementations, the second resin 410 comprises a tension-cyclable resin. The tension-cyclable resin includes a tensile-survivable index matched resin. In alternative implementations, the first resin 408 and the second resin 410 are identical.

The display 106 may further include a hard-coating 412. Although illustrated in FIG. 4 as a separate and distinct portion of the display 106, it will be understood by those skilled in the art that the hard-coating 412 is not a layer (e.g., a protective film), but a coating. Thus, the first glass layer 110-1 is said to be user-exposed since a user may directly interact with the first glass layer 110-1 and hard-coating 412 as opposed to a protective film or the like.

The hard-coating 412 may be a thin coat of hard and transparent material composed of substances like silicon dioxide. The hard-coating 412 may improve scratch resistance and durability. The hard-coating 412 may also be applied to the first resin 408.

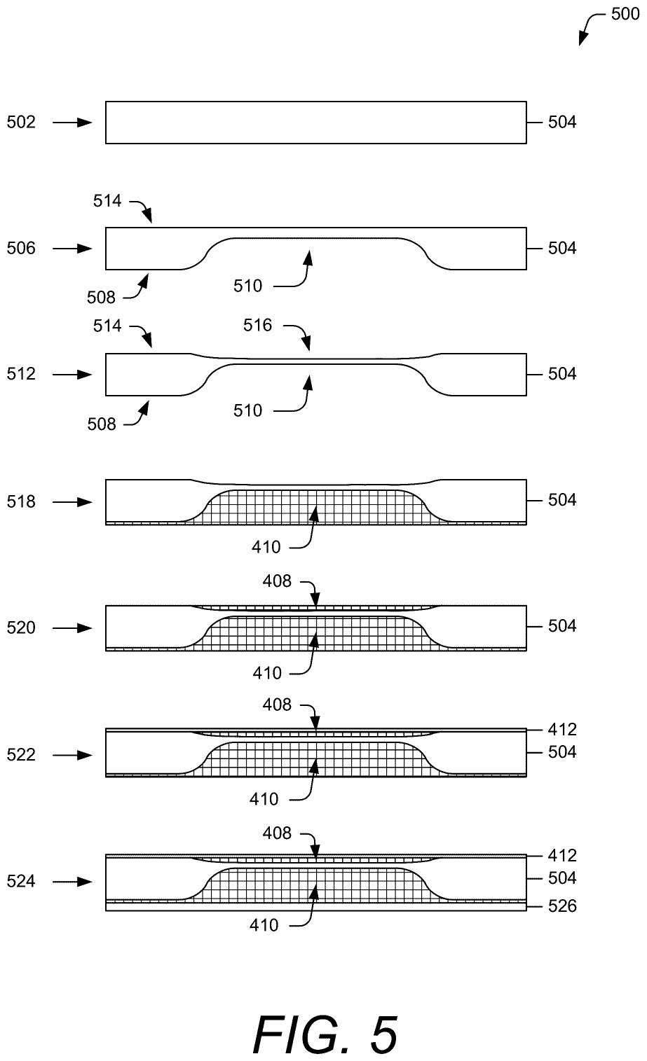

FIG. 5 illustrates example manufacturing steps 500 in accordance with one or more implementations. As illustrated, a step 502 includes a glass layer 504 that may be cut to shape (e.g., a elliptical prism, a rectangular prism). At a step 506, a first side 508 may be etched by a first etching process, such as a chemical bath, acid etching, and/or laser etching, to form a first groove 510 in the glass layer 504. At a step 512, a second side 514 may be etched by a second etching process to form a second groove 516 in the glass layer 504. The first etching process and the second etching process may be the same or different processes. In some implementations, the first side 508 and the second side 514 are etched simultaneously. At a step 518, the second resin 410 may be applied to the first groove 510. At a step 520, the first resin 408 may be applied to the second groove 516. The first resin 408 and a second resin 410 may be applied concurrently or sequentially. At a step 522, a hardcoating 412 may be applied to the first side 508 of the glass layer 504. At a step 524, a removeable optically-clear adhesive 526 may be applied to the second side 514 (e.g., the bottom face) of the glass layer 504. The foldable display structure may then be integrated into a foldable electronic device by adhering the second side 514 of the foldable display structure to a display panel (not illustrated).

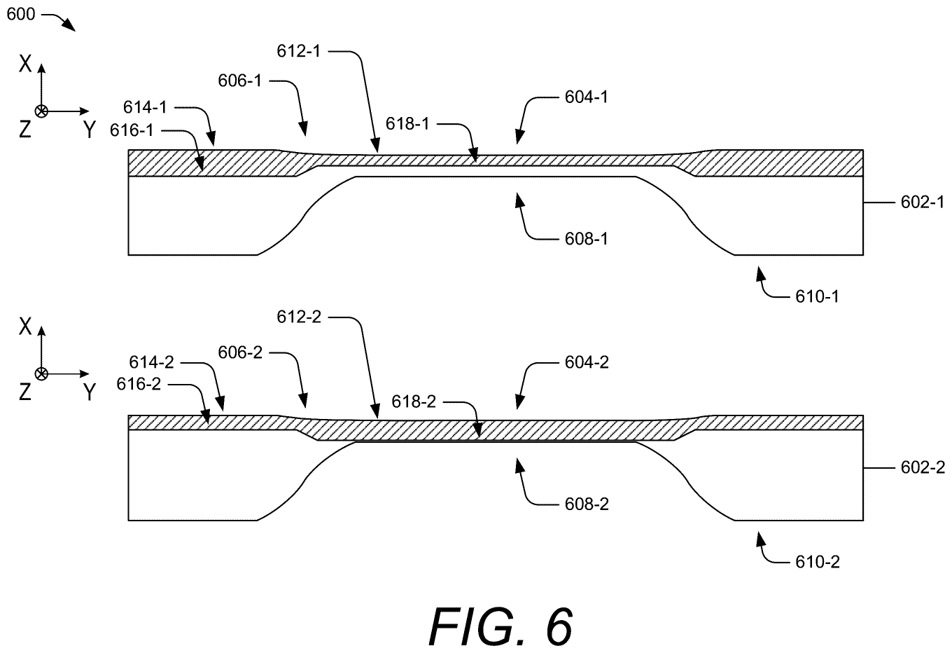

FIG. 6 illustrates two example implementations 600 of a glass layer comprising a non-uniform chemical strengthening depth. The glass layer may be strengthened by a chemical process (e.g., ion exchange, ion implantation, plasma treatment) that may improve aspects (e.g., shatter resistance, scratch resistance, compression and tension cycling) of a portion of the glass layer above the strengthening depth. As illustrated, a first glass layer 602-1 includes a first groove 604-1 on a top face 606-1 and a second groove 608-1 on a bottom face 610-1 (e.g., the top face 606-1 being exposed to an ambient environment, the bottom face 610-1 positioned proximally closer to a display panel). The first groove 604-1 and the second groove 608-1 form a variable thickness in the first glass layer 602-1 along at least one dimension of the first glass layer 602-1 (e.g., a dimension perpendicular to a length of the groove, the Y-axis). The first groove 604-1 and the second groove 608-1 may define, in the first glass layer 602-1, a thin region 612-1 and at least one thick region 614-1. In implementations, a ratio of the dimensional-thickness between the at least one thick region 614-1 and the thin region 612-1 may be at least six-to-one. In one example, the at least one thick region 614-1 may be 200 micrometers thick, while the thin region 612-1 may be 30 micrometers thick.

The at least one thick region 614-1 may have a chemical strengthening depth 616-1, and the thin region 612-1 may have a chemical strengthening depth 618-1. The chemical strengthening depth 616-1 of the thick region 614-1 may be farther from the top face 606-1 than the chemical strengthening depth 618-1 of the thin region 612-1.

Further illustrated, a second glass layer 602-2 includes a first groove 604-2 on a top face 606-2 and a second groove 608-2 on a bottom face 610-2 (e.g., the top face 606-2 being exposed to an ambient environment, the bottom face 610-2 positioned proximally closer to a display panel). Further illustrated, the first groove 604-2 and the second groove 608-2 form a variable thickness in the first glass layer 602-2 along at least one dimension of the first glass layer 602-2 (e.g., a dimension perpendicular to a length of the groove, the Y-axis). The first groove 604-2 and the second groove 608-2 may define, in the first glass layer 602-2, a thin region 612-2 and at least one thick region 614-2. In implementations, a ratio of the dimensional-thickness between the at least one thick region 614-2 and the thin region 612-2 may be at least six-to-one. In one example, the at least one thick region 614-2 may be 200 micrometers thick, while the thin region 612-2 may be 30 micrometers thick.

The at least one thick region 614-2 may have a chemical strengthening depth 616-2, and the thin region 612-2 may have a chemical strengthening depth 618-2. The chemical strengthening depth 616-2 of the thick region 614-2 may be farther from the top face 606-2 than the chemical strengthening depth 618-2 of the thin region 612-2. In further implementations, a strengthening depth may be uniform or may vary substantially within a one or more thick regions or within a thin region.

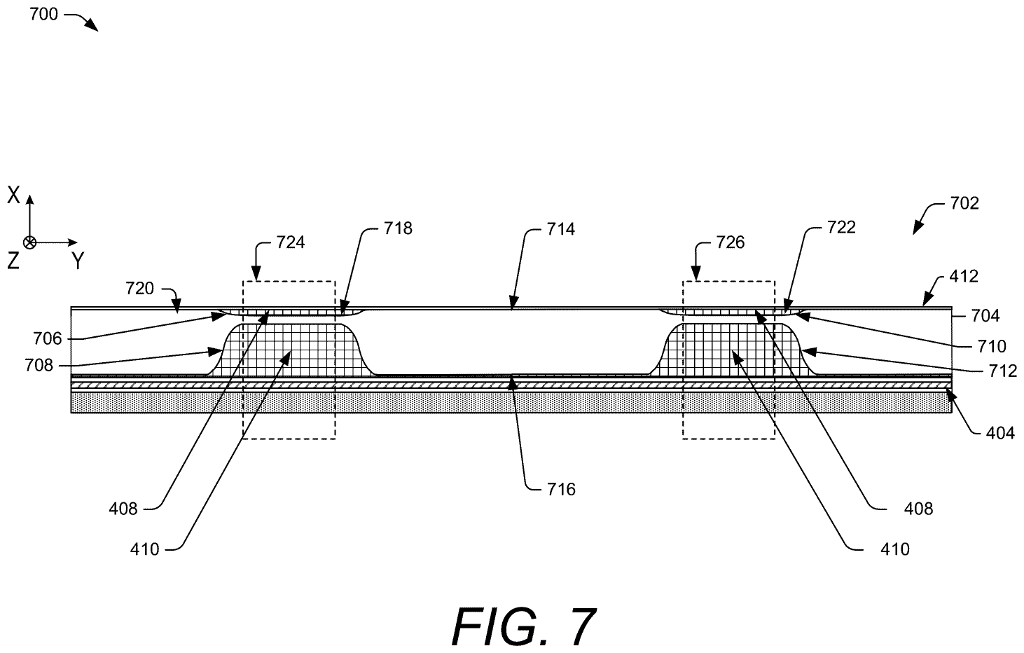

FIG. 7 illustrates an example implementation 700 of a display 702 in accordance with one or more implementations. The display 702 includes a glass layer 704. As illustrated, the glass layer 704 includes a first groove 706, a second groove 708, a third groove 710 and a fourth groove 712. In implementations, the first groove 706 and the third groove 710 are on a top face 714 of the glass layer 704 and the second groove 708 and the fourth groove 712 are on a bottom face 716 of the glass layer 704.

As illustrated, in the glass layer 704, the first groove 706 is shallower in depth than the second groove 708, and the third groove 710 is shallower in depth than the fourth groove 712. In implementations, the depths of the first groove 706 and the second groove 708 are not dependent on the depths of the third groove 710 and the fourth groove 712. In at least some implementations, the first groove 706 may be equal in depth to the second groove 708 and the third groove 710 may be equal in depth to the fourth groove 712. In alternative implementations, the first groove 706 is greater in depth than the second groove 708 and the third groove 710 is greater in depth than the fourth groove 712.

As illustrated, in the glass layer 704, a width of the first groove 706 is narrower than a width of the second groove 708 and the width of the third groove 710 is narrower than a width of the fourth groove 712. In implementations, the width of any one groove is not dependent on the width of any other groove. In at least some implementations, a width of the first groove 706 is wider than a width of the second groove 708 and the width of the third groove 710 is wider than a width of the fourth groove 712. In alternative implementations, a width of the first groove 706 is equal to a width of the second groove 708 and a width of the third groove 710 is equal to a width of the fourth groove 712.

The first groove 706 and the second groove 708 may be aligned along a first plane. The first plane may be normal to the top face 714 of the glass layer 704. The third groove 710 and the fourth groove 712 may be aligned along a second plane. The second plane may be normal to the top face 714 of the glass layer 704.

Further illustrated, the first groove 706, the second groove 708, the third groove 710, and the fourth groove 712 form a variable thickness in the glass layer 704 along at least one dimension of the glass layer 704 (e.g., a dimension perpendicular to a length of the groove, the Y-axis). The first groove 706 and the second groove 708 may define, in the glass layer 704, a first thin region 718 and at least one thick region 720. In implementations, a ratio of the dimensional-thickness between the at least one thick region 720 and the first thin region 718 may be at least six-to-one. In one example, the at least one thick region 720 may be 200 micrometers thick, while the first thin region 722 may be 30 micrometers thick.

The third groove 710 and the fourth groove 712 may define, in the glass layer 704, a second thin region 722 and the at least one thick region 720. In implementations, a ratio of the dimensional-thickness between the at least one thick region 720 and the second thin region 722 may be at least six-to-one. In one example, the at least one thick region 720 may be 200 micrometers thick, while the second thin region 722 may be 30 micrometers thick.

At least portions of the first groove 706 and the second groove 708 define a first foldable region 724. For example, a portion of the first thin region 718 may bend when mechanical forces are applied to the at least one thick region 720. A thickness in the first foldable region 720 and/or a thickness in non-folding regions at least partially determine a mechanical strength of the glass layer 704.

At least portions of the third groove 710 and the fourth groove 712 define a second foldable region 726. For example, a portion of the second thin region 722 may bend when mechanical forces are applied to the at least one thick region 720. A thickness in the second foldable region 726 and/or a thickness in non-folding regions at least partially determine a mechanical strength of the glass layer 704.

In aspects, the first groove 706 and the third groove 710 of the glass layer 704 are filled with the first resin 408 and the second groove 708 and the fourth groove 712 are filled with the second resin 410. In implementations, the first resin 408 fills only the first groove 706 and the third groove 710 such that the first resin 408 is contiguous with the top face 714 of the glass layer 704. For example, the first resin 408 is flush with a surface of the top face 714 of the glass layer 704. In further implementations, the second resin 410 extends beyond the second groove 708 and the fourth groove 712, covering an entire surface of the bottom face 716 of the glass layer 704. For example, the second resin 410 is disposed between all portions of the permanent protective layer 404 and the glass layer 704. In at least some implementations, the second resin 410 fills only the second groove 708 and the fourth groove 710 such that the second resin 410 is contiguous with the bottom face 716 of the glass layer 704.

The display 702 may further include the hard-coating 412. Although illustrated in FIG. 7 as a separate and distinct portion of the display 702, it will be understood by those skilled in the art that the hard-coating 412 is not a layer (e.g., a protective film), but a coating. Thus, the glass layer 704 is said to be user-exposed since a user may directly interact with the glass layer 704 and hard-coating 412 as opposed to a protective film or the like. The hard-coating 412 may also be applied to the first resin 408.

### CONCLUSION

Unless context dictates otherwise, use herein of the word “or” may be considered use of an “inclusive or,” or a term that permits inclusion or application of one or more items that are linked by the word “or”. Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying Drawings and terms discussed herein may be indicative of one or more items or terms, and thus reference may be made interchangeably to single or plural forms of the items and terms in this written description.

Although implementations directed at user-exposed and variably-thick cover glass for foldable displays have been described in language specific to certain features and/or methods, the subject of the appended Claims is not necessarily limited to the specific features or methods described. Rather, the specific features and methods are disclosed as example implementations directed at user-exposed and variably-thick cover glass for foldable displays.

What is claimed is:

1. A foldable display structure comprising:
a glass layer having a top face and an opposing bottom face, the glass layer positioned as the topmost layer of the foldable display structure, the glass layer comprising:
a first groove on the top face of the glass layer along a first plane; and
a second groove on the bottom face of the glass layer along the first plane, the first groove and the second groove forming a variable thickness in the glass layer along a dimension of the glass layer perpendicular to the first plane sufficient to define a foldable region;
a first resin deposited within the first groove, the first resin contiguous with the top face of the glass layer; and
a second resin deposited within the second groove.

2. The foldable display structure of claim 1, wherein the first plane is normal to the top face of the glass layer.

3. The foldable display structure of claim 2, wherein the first groove and the second groove forming the variable thickness in the glass layer along the dimension of the glass layer perpendicular to the first plane define a thick region and a thin region in the glass layer, and wherein the variable thickness between the thick region and the thin region comprise a ratio of at least six-to-one.

4. The foldable display structure of claim 1, wherein:
the first groove comprises a first depth shallower than or equal to a second depth of the second groove; and
the first groove comprises a first width narrower than or equal to a second width of the second groove.

5. The foldable display structure of claim 1, wherein the first resin comprises a compression-cyclable resin, the compression-cyclable resin comprising a compression-survivable index matched resin.

6. The foldable display structure of claim 1, wherein the second resin comprises a tension-cyclable resin, the tension-cyclable resin comprising a tensile-survivable index matched resin.

7. The foldable display structure of claim 1, wherein the first resin and the second resin comprise the same resin.

8. The foldable display structure of claim 1, wherein the foldable region of the foldable display structure is defined by at least portions of the first groove and the second groove.

9. The foldable display structure of claim 1, wherein:
the first groove and the second groove are manufactured into the glass layer in a two-sided etching process; or
the first groove and the second groove are manufactured into the glass layer in separate single-sided etching processes.

10. The foldable display structure of claim 1, further comprising a hard-coating applied to the top face of the glass layer.

11. The foldable display structure of claim 1, wherein the glass layer comprises a non-uniform chemical strengthening depth.

12. The foldable display structure of claim 1, wherein the foldable display structure is integrated within an electronic device.

13. The foldable display structure of claim 12, wherein:
the electronic device comprises a display module; and
an optically clear adhesive adheres the foldable display structure to the display module.

14. The foldable display structure of claim 1, wherein the top face of the glass layer comprises at least one of a rectangular shape or an elliptical shape.

15. The foldable display structure of claim 1, further comprising:
a third groove on the top face of the glass layer along a second plane; and
a fourth groove on the bottom face of the glass layer along the second plane, the third and fourth grooves sufficient to produce a variable thickness in the glass layer along a second dimension of the glass layer perpendicular to the second plane;
a third resin deposited within the third groove, the third resin contiguous with the top face of the glass layer; and
a fourth resin deposited within the fourth groove.

16. The foldable display structure of claim 15, wherein the second plane is normal to the top face of the glass layer.

17. The foldable display structure of claim 15, further comprising:
a first foldable region defined by at least portions of the first groove and the second groove; and
a second foldable region defined by at least portions of the third groove and the fourth groove.

18. The foldable display structure of claim 15, wherein:
the third groove comprises a third depth shallower than or equal to a fourth depth of the fourth groove; and
the third groove comprises a third width narrower than or equal to a fourth width of the fourth groove.

19. The foldable display structure of claim 1, further comprising:
a permanent protective layer, the permanent protective layer positioned underneath the glass layer and the second resin.

20. The foldable display structure of claim 19, wherein the second resin extends beyond the second groove, the second resin disposed between all portions of the permanent protective layer and the glass layer.
